(19) United States
(12) Patent Application Publication
(10) Pub. No.: US 2024/0009986 A1
(43) Pub. Date: Jan. 11, 2024

(54) FILM FOR DEICING AND ELECTROMAGNETIC INTERFERENCE SHIELDING APPLICATIONS

(71) Applicant: UTI LIMITED PARTNERSHIP, CALGARY (CA)

(72) Inventors: Ehsan HOSSEINI, Kelowna (CA); Kunai KARAN, Calgary (CA); Uttandaraman SUNDARARAJ, Calgary (CA); Mohammad ARJMAND, Kelowna (CA)

(21) Appl. No.: 18/014,907

(22) PCT Filed: Jun. 30, 2021
(86) PCT No.: PCT/CA2021/050902

§ 371 Date: Jan. 6, 2023

Related U.S. Application Data
(60) Provisional application No. 63/048,266, filed on Jul. 6, 2020.

(51) Int. Cl. B32B 37/24; H05B 3/84; B32B 15/02

(52) U.S. Cl. CPC B32B 37/24; H05B 3/84; B32B 15/02; H05B 2203/013; H05B 2214/04; B32B 2311/08; B32B 2307/412; B32B 2307/308

(57) ABSTRACT

The present disclosure generally relates to a method of producing a film for use with de-icing and EMI shielding. The film is a multilayer film on a substrate comprising a layer of PEFOT:PSS, a AgNW layer and a second PEDOT:PSS layer. The film is produced by a simple low-cost fabrication method and does not require vacuum, pressing or high temperature processing.

### CROSS REFERENCE TO RELATED APPLICATION

This application claims priority to United States Provisional Patent Application number U.S. 63/048,266, filed Jul. 6, 2020, the entire contents of which is hereby incorporated by reference.

### FIELD

The present disclosure relates a method of producing a film for use with deicing and EMI shieling.

### BACKGROUND

Transparent indium tin oxide (ITO)-based electrodes are widely used in a different range of electronic devices, including touch screens, solar cells, transistors, and light-emitting diodes.¹⁻⁴ Recently, ongoing research has been focused on the development of transparent glass heaters (TGHs) for vehicles windshield defrosters,⁵ outside displays, heat maintaining windows, solar voltaic cells, mirrors, and camera lenses⁶⁻⁹ as well as lightweight transparent electromagnetic interference (EMI) shields¹⁰ for wireless communications, optical windows, medical equipment, optoelectronic displays for military and electro-optical sensor pods for aerospace¹¹⁻¹⁴ as alternative transparent conductors (TCs) to replace the existing ITO-based electrodes. However, the commonly-known drawbacks of ITO such as limited availability, high cost, and relative toxicity have turned the focus of the TCs market to other indium-free alternatives such as Zinc oxides (ZnOs),^{15,16} carbon nanotubes (CNTs),^{17,18} graphene,¹⁹⁻²¹ metal nanowires and nanofibers,²²⁻²⁴ metal meshes,^{25,26} and hybrid materials.^{27,28} Yet, these materials have been struggling to reach the standards set by the industry to act as a TC²⁹ and make their way into the commercialization step.

Ga- and Al-doped ZnOs are brittle³⁰ and form cracks inside the film,₃₁ resulting in the reduction of conductivity,₃₂ which ultimately makes the device fail. They also require high vacuum deposition, which creates issues such as instrumental complexity, high cost,₃₃ and imperfect scalability.₃₄ Carbon-based film heaters need higher power consumption due to their high sheet resistance₃₅₋₃₇ and have inferior optical features than that of ITO._{35,38} They can probably never reach the requirements to act as a transparent heater or shield on their own₃₉ and may be used in combination with other materials in less challenging applications.₄₀ Instead, metal nanowires (NWs) deliver both higher conductivity and transparency, though their network is random,₄₁ percolation-limited,₄₂ and resistance dominating.₄₃ The large cross nanowire junction resistance, as a common bottleneck in NWs networks,₄₄ caused by the redundant wires that are not part of the network, increases the surface roughness of the film₄₅ and may eventually induce hot spots in the heater. The poor adhesion between NWs and common substrates makes them unfeasible in harsh environments for prolonged operations._{46,47} To control the uniform distribution of NWs inside the prepared films, the metal mesh has been developed, using the crackle fabrication method to hold a highly interconnected and percolated network with very low resistance (<5 Ωsq₋₁). The approach achieved early market acceptance but reportedly has lost the favor today. Despite the high conductivity attained through the crackle mesh process, Ag mesh adhesion to glass substrate needs additional treatment by Ti/Cr layer before deposition. Also, Joule heating may accelerate electrical failure, owing to the high current density that can result in melting, electro-migration,₄₈₋₅₀ and corrosion₅₁ of the NWs. Furthermore, some cracks may form incompletely and not crack properly.₅₂ This is due to the critical thickness below which cracking will not occur.₅₃ The thickness depends on many factors, including the nature of crackle dispersion, particle type and size, and the solvent being used.₅₄ Nevertheless, as the patterning area becomes larger for industrial applications, the crackle fabrication of thin films becomes challenging and cost-prohibitive. The lack of ability to control the consistent crackle pattern formation for larger areas will lead to disparate overall performance of the films. Furthermore, the formation of microgrooves on rigid substrates such as glass is problematic.₂₅ As a result, metal meshes are no longer in the interest of the industrial market for the facile production of low-cost TCs. In terms of shielding electromagnetic (EM) waves, metals of any forms, in general, are not favorable candidates for transparent EMI shields due to their heavy weight, corrosion vulnerability, and stiffness as their major disadvantages.₅₅

According to a recent assessment report, although ITO holds nearly all of the TC market at the moment, the non-ITO TC market has kept growing from less than USD 1 billion in 2015 and will reach nearly USD 11 billion by 2022 (FIG. 1).₅₆ Beside various exotic TC materials under development, the majority of technologies that have reached the market are Ag-based among which silver nanowire (AgNW) plays the dominant role in replacing ITO-based materials, benefitting from its competitor's missteps.₅₇ Yet, despite being the highest conductive material, AgNWs demand extra treatments such as high temperature and longtime thermal annealing,_{26,58} strong conformal pressure,_{45,59,60} vacuum filtration_{61,62} and HCl vapor treatment₆₃ to reduce the contact resistance between the wires. Moreover, the adhesion of AgNWs to the substrates always requires surface modification,₆₂ including encapsulation,₅₈ in situ polymerization,_{64,65} and nail polish liquid.₆₃ To circumvent the aforementioned drawbacks from relying only on a single AgNWs component, studies have shifted towards hybrid electrodes of AgNWs and intrinsically conductive polymers (ICPs) such as poly(3,4-ethylenedioxythiophene):poly(styrene sulfonate), also known as PEDOT:PSS in a composite ink form or layer by layer (LBL) assembly (Table 1). However, the resulting TGHs and transparent EMI shields to date have struggled to achieve a transmittance greater than 90% and a sheet resistance (Rₛ) of less than 10 Ωsq_{-1.66}

TABLE 1

| | Summary of studies on PEDOT:PSS/AgNWs composites | | | | | | | | | |
|---|---|---|---|---|---|---|---|---|---|---|
| | | | | | | AgNWs | | | | |
| | | | | AgNWs | | diameter | T(%) @ | Rₛ | Printing | |
| Structure | Assembly | Additives/fillers | t (nm) | concentration | | (nm) | 550 nm | (Ω sq⁻¹) | technique | Ref. |
| Composite | ink | — | — | 4-12 | mg/ml | 100 | 82.3-74.1 | 4000-500 | Screen printing | 91 |
| LBL | 1. Ag-grid | WO₉ nanoparticles | — | 14 | wt % | 3-4 μm | 70 | 0.62 | 1. Sintering | 47 |
| | 2. PEDOT:PSS | | | AgNPs | | | | | 2. Spin coating | |
| | 3. WO₃ | | | | | | | | 3. Electrodeposition | |
| Composite | ink | MeOH, DMSO, EG | 160 | 0.5 | wt % | 30 | 90 | 15 | Slot-die roll coating | 92 |
| LBL | 1. AgNWs | — | 200 | 2.5 | mg/ml | 62.5 | 83.8 | 11.6 | 1. Doctor blading | 93 |
| | 2. PEDOT:PSS | | | | | | | | 2. Spin coating | |
| Composite | ink | MeOH, DMSO, EG, | — | 30 | wt % | 20 | 92 | 20 | Meyer bar coating | 94 |
| | | silane | | | | | | | | |
| LBL | 1. PEDOT:PSS | Photopolymer | 500 | 0.5 | mg/ml | 10 | ~95 | 195 | 1. Spin coating | 95 |
| | 2. AgNWs | (NOA63) | | | | | | | 2. Template stripping | |
| | 3. Photopolymer | | | | | | | | | |
| LBL | 1. PEDOT:PSS (3 layers) | — | >300 | 1.5 | mg/ml | 40 ± 5 | 83.95 | 21.98 | Spin coating | 67 |
| | 2. AgNWs (5 layers) | | | | | | | | | |
| | 3. PEDOT: PSS (3 layers) | | | | | | | | | |
| Composite | ink | DMSO, imidazole, | 100 μm | 5 | mg/ml | 57 | >90 | 75 | Slot-die roll coating | 96 |
| | | tetraethyl | | | | | | | | |
| | | orthosilicate | | | | | | | | |
| LBL | 1. AgNWs | IPA | — | 0.003 | mg/ml | — | 82 | 25 | Meyer rod coating | 68 |
| | 2. PEDOT:PSS | | | | | | | | | |
| LBL | 1. AgNWs | Guanidine, DMSO | — | 2 | mg/ml | — | 83-84.8 | 29 | Spin coating | 97 |
| | 2. AgNWs | | | | | | | | | |
| | 3. PEDOT:PSS | | | | | | | | | |
| LBL | 1. AgNWs | DMSO, Zonyl | — | 0.3 | wt % | 30 | 91 | 26.8 | Spin coating | 98 |
| | 2. PEDOT:PSS | | | | | | | | | |
| LBL | 1. PEDOT:PSS | — | 150 | — | | 25 | 86 | 12 | 1. Spin coating | 45 |
| | 2. AgNWs | | | | | | | | 2. Drop casting | |
| | | | | | | | | | 3. Hot pressing | |
| LBL | 1. PEDOT:PSS | DMSO | 160 | 0.1 | mg/ml | 115 | 81.7 | 10.76 | Spray coating | 99 |
| | 2. AgNWs | | | | | | | | | |
| LBL | 1. AgNWs | TiO₂ NPS | — | 0.05 | mg/ml | 40-100 | 83 | 15 | 1. Spray coating | 100 |
| | 2. TiO₂ NPs | | | | | | | | 2. Spin casting | |
| | 3. PEDOT:PSS | | | | | | | | | |
| Composite | ink | — | ~100 | 0.1 | wt % | 30 | 88.64 | 19.7 | Brush painting | 101 |
| Composite | ink | SWCNTs | >200 | 0.1 | mg/ml | 100-200 | 86 | 4-7 | 1. Roll-to-roll | 102 |
| | | | | | | | | | 2. Spin coating | |
| LBL | 1. PEDOT: PSS (20 nm) | | ~80 | 5 | mg/ml | 60 | 91 | 6.4 | Spin casting | This |
| | 2. AgNWs | | | | | | | | | work |
| | 3. PEDOT: PSS (20 nm) | | | | | | | | | |

### SUMMARY

In one aspect there is provided a method of producing a film, comprising:
applying a first layer of PEFOT:PSS on a substrate, and subjecting said first layer to a first annealing temperature for a first annealing time,
applying an AgNW layer on said first layer of PEFOT:PSS, and subjecting said AgNW layer to an AgNW annealing temperature for an AgNW annealing time, and
applying a second layer of PEDOT:PSS on the AgNWs layer, and subjecting said second layer to a second annealing temperature for a second annealing time.

In one example, said applying comprises spin coating.

In one example, said first annealing temperature is about 120° C. to 180° C., preferably 160° C., and said second annealing is about 120° C. to 180° C., preferably about 160° C.

In one example, said first annealing time is about 5 minutes to 30 minutes, preferably 10 minutes, and said second annealing time is about 5 minutes to 30 minutes, preferably about 10 minutes.

In one example, said AgNW annealing temperature is about 60° C. to 160° C., preferably about 120° C.

In one example, said AgNW is AgNWs-30, AgNWs-60, or AgNWs-90.

In one example, the concentration of AgNW used in the coating step is about 0.1 mg/ml to 15 mg/ml, preferably about 5 mg/ml.

In one example, said first layer of PEFOT:PSS has a thickness of about 2 nm to 100 nm, preferably about 20 nm, and said second layer of PEFOT:PSS has a thickness of about 2 nm to 100 nm, preferably about 20 nm.

In one example, said substrate comprises or consists of glass or silicon.

In one example, the film has a thickness of about 5 nm to 150 nm, preferably about 80 mm.

In one aspect there is provided a film produced by the method of any one of claims 1-10.

In one example, the film has a transparency of greater than about 80%, preferably greater than about 90%.

In one example, the film has an EMI shielding effectiveness of 10 dB to 50 dB, preferably 23 dB, when used as a transparent EMI shield.

In one aspect there is provided a film produced by the method of any one of claims 1-10 for use in deicing.

In one aspect there is provided a film produced by the method of any one of claims 1-10 for use in EMI shielding.

### BRIEF DESCRIPTION OF THE FIGURES

Embodiments of the present disclosure will now be described, by way of example only, with reference to the attached Figures.

FIG. 1 Non-ITO transparent conductor market revenue forecast.¹ The revenue in USD.

FIG. 2. Schematic of sample preparation initiated by coating (a) 20 nm PEDOT:PSS first layer followed by (b) AgNWs coating and (c) second 20 nm PEDOT:PSS layer deposition. (d) The soldering of AgNWs by PEDOT:PSS.

FIG. 3 (a) Raman spectroscopy and (b) XRD diffractometry of PEDOT:PSS/AgNWs-60, and PEDOT:PSS/AgNWs-60/PEDOT:PSS thin films. The numbers in brackets are the XRD reflections of the metallic silver structure.

FIG. 4. (a) Optical microscopy, (b) SEM, and (c to e) AFM amplitude images of the AgNWs-coated PEDOT:PSS thin film. All images are for AgNWs-60.

FIG. 5. (a) Optical microscopy, (b) side view SEM, (c and d) AFM amplitude, (e) height variation, and (h) TEM images of AgNWs, sandwiched between PEDOT:PSS layers. (f) Optical microscopy, and (g) TEM images of broken melted AgNWs coated on PEDOT:PSS. All images are for AgNWs-60.

FIG. 6. Correlation of sheet resistances (Rs) and total EMI shielding effectiveness (SE_{T}) of (a) 30, (b) 60, and (c) 90 nm-diameter AgNWs with different NWs concentrations. The AgNWs concentrations order on the glass substrates are 1, 2, 3, 4 (top row from left), 5, 8, 10, and 12 mg/ml (bottom row from left).

FIG. 7 UV-Vis transmittance of a blank glass substrate, pristine PEDOT:PSS, PEFOT:PSS/AgNWs-60, and PEDOT:PSS/AgNWs-60/PEDOT:PSS thin films.

FIG. 8. Deicing apparatus (a) before and (c) after de-icing, where the temperatures of different 9 spots (Sp1 to 9) were constantly monitored (b and d), using a forward-looking infrared (FLIR) thermal imaging camera.

FIG. 9 Initial temperature control and monitoring of the Styrofoam sample holder inside the environmental chamber maintained at −10° C. Nine different spots (Sp1 to 9) were scanned continuously, using a thermal FLIR imaging camera.

FIG. 10 Schematic of the temperature uniformity profile across the film heater at SP5, 9, 4, and 7, spots.

FIG. 11. Correlation between (a) optical transmission and sheet resistance together and (b) with the figure of merit for the previous studies on transparent conductive electrodes (TCEs) based on PEDOT:PSS and AgNWs.

FIG. 12. (a) Schematic of obtained reflectance, absorbance, and transmittance along with (b) EMI shielding reflection loss, absorption loss, and the overall shielding effectiveness for the ˜80 nm PEDOT:PSS/AgNWs-60/PEDOT:PSS nanocomposite with AgNWs concentration of 5 mg/ml.

FIG. 13 (a) A thick Styrofoam sheet with cuts designed for placing the 5×4 cm2 glass substrates, (b) 2 mm ice-coated glass substrates with Parafilm layers underneath, (c) the glass substrate sizes and assembly set-up to resemble a ˜5 mm vehicle windshield and (d) the V-shaped trench drain made of Styrofoam for holding the deicing apparatus.

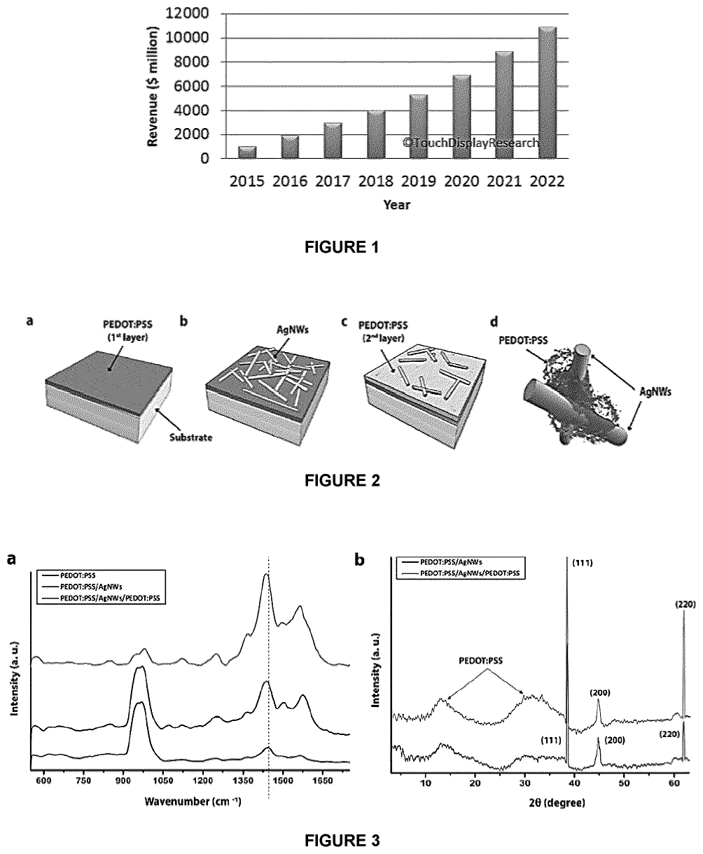

### DETAILED DESCRIPTION

The present disclosure relates a method of producing a film for use with deicing and EMI shieling.

In one aspect there is provided a method of producing a film, comprising:
applying a first layer of PEFOT:PSS on a substrate, and subjecting said first layer to a first annealing temperature for a first annealing time,
applying an AgNW layer on said first layer of PEFOT:PSS, and subjecting said AgNW layer to an AgNW annealing temperature for an AgNW annealing time, and
applying a second layer of PEDOT:PSS on the AgNWs layer, and subjecting said second layer to a second annealing temperature for a second annealing time.

The term “film” as used herein refers to a thin layer of a substance or composition. In some examples, films may be in solid or semi-solid form and, thus, are inclusive to solid substances and gels. The term “film” encompasses a layer that is formed in-situ or preformed, and which is not capable of self-support, and includes a layer that may be described either as a film or coating. The coating or film has a thickness within the range of thicknesses specified in the specification. The coating or film is also referred to herein as a coating/film.

The terms “applying” or “application” is used with regard to the treatment with a flowable composition, such as a liquid and/or fluid. In some examples, this refers to the flowable composition applied to a surface (e.g., to a substrate or PEFOT:PSS layer) such that the surface is fully or partially wetted or contacted by the flowable composition. In some examples, applying may refer to selected portions of the surface or all of the surfaces.

The terms “on”, “appended to”, “affixed to”, “bonded to”, “adhered to” or terms of like import means that the subject coating, film, or layer is either directly connected to (superimposed on and in direct contact with) the object surface, or indirectly connected to the object surface through one or more other coatings, films or layers.

The term “substrate” as used herein means an article having at least one surface that is capable of accommodating a coating or film.

As used herein the terms “about” and “approximately” refers to ±10%.

In one example, said applying comprises spin coating.

The term “spin coating” refers to a particular process used to deposit uniform thin films or layers onto flat substrates. Generally, in “spin coating,” a small amount of coating material is applied to the center of the substrate, which is either spinning at low speed or not spinning at all. The substrate is then rotated at specified speeds in order to spread the coating material uniformly by centrifugal force.

In one example, said first annealing temperature is about 120° C. to 180° C., preferably 160° C., and said second annealing is about 120° C. to 180° C., preferably about 160° C.

In one example, said first annealing time is about 5 minutes to 30 minutes, preferably 10 minutes, and said second annealing time is about 5 minutes to 30 minutes, preferably about 10 minutes.

In one example, said AgNW annealing temperature is about 60° C. to 160° C., preferably about 120° C.

In one example, said AgNW is AgNWs-30, AgNWs-60, or AgNWs-90.

In one example, said the concentration of AgNW used in the coating step is about 0.1 mg/ml to 15 mg/ml, preferably about 5 mg/ml.

In one example, said first layer of PEFOT:PSS has a thickness of about 2 nm to 100 nm, preferably about 20 nm, and said second layer of PEFOT:PSS has a thickness of about 2 nm to 100 nm, preferably about 20 nm.

In one example, said substrate comprises or consists of glass or silicon.

In one example, the film has a thickness of about 5 nm to 150 nm, preferably about 80 mm.

In one aspect there is provided a film produced by the method as described herein.

In one aspect there is provided a film produced by the method of any one of claims 1-10.

In one example, the film has a transparency of greater than about 90%.

The terms “transparency” or “transparent”, as used herein, for example in connection with a film, material, and/or coating, means that the indicated coating, film, and/or material has the property of transmitting light without appreciable scattering so that objects lying beyond are seen clearly.

In one example, the film has an EMI shielding effectiveness of 10 dB to 50 dB, preferably 23 dB, when used as a transparent EMI shield.

The terms “EMI (electromagnetic interference) shield” or “EMI (electromagnetic interference) shielding” refers to shielding against electromagnetic disturbances, such as radiofrequency interference.

In one aspect, there is provided a film produced by a method as described herein for use in deicing.

In one aspect, there is provided a film produced by the method of any one of claims 1-10 for use in deicing.

In one aspect, there is provided a film produced by a method as described herein for use in EMI shielding.

In one aspect, there is provided a film produced by the method of any one of claims 1-10 for use in EMI shielding.

Method of the invention is conveniently practiced by providing the compounds and/or compositions used in such method in the form of a kit. Such kit preferably contains the composition. Such a kit preferably contains instructions for the use thereof.

To gain a better understanding of the invention described herein, the following examples are set forth. It should be understood that these examples are for illustrative purposes only. Therefore, they should not limit the scope of this invention in any way.

### Examples

Abstract

An unprecedented highly transparent glass heater and EMI shield is fabricated, using a layer-by-layer assembly of PEDOT:PSS and AgNWs in order to replace both the conventional ITO and other metal- and carbon-based electrodes proposed to date. The novel simple fabrication of the electrode, unlike many other reported technologies, does not require any vacuum, pressing, or high temperature processing. The ˜80 nm hybrid thin film with the high figure-of-merit of 610 presents the low sheet resistance of 6.4 Ωsq-1 and total EMI shielding of 23 dB at the high transparency of 91%. The transparent heater, sandwiched in between two ˜2.5 mm glass substrates, shows promising in Joule heating application when successfully de-ices a 2 mm ice while maintained under the sub-zero temperature of −10° C. in less than a minute.

Herein, we introduce a low-cost, simple solution processing method without further addition of a solvent or an extra filler for the fabrication of a >90% transparency ultrathin film that can be applied both as a TGH electrode and an EMI shield, using the merits of PEDOT:PSS and AgNWs. The developed ˜80 nm film, consisting of AgNWs sandwiched between PEDOT:PSS layers, was found to be capable of deicing a 2 mm thick ice on a 5 mm thick glass substrate, mimicking a vehicle windshield, in less than a minute at temperatures as cold as −10° C. The ˜80 nm film also offered a substantial total EMI shielding effectiveness of 23 dB when used as a transparent EMI shield. To the best of our knowledge, the sandwich technique has been used only by one study to date where the abundant number of layers of AgNWs and PEDOT:PSS could only provide a thicker film (>300 nm) with lower transparency (83.95%) and very higher sheet resistance (21.98 Ωsq₋₁).₆₇

Results and Discussion

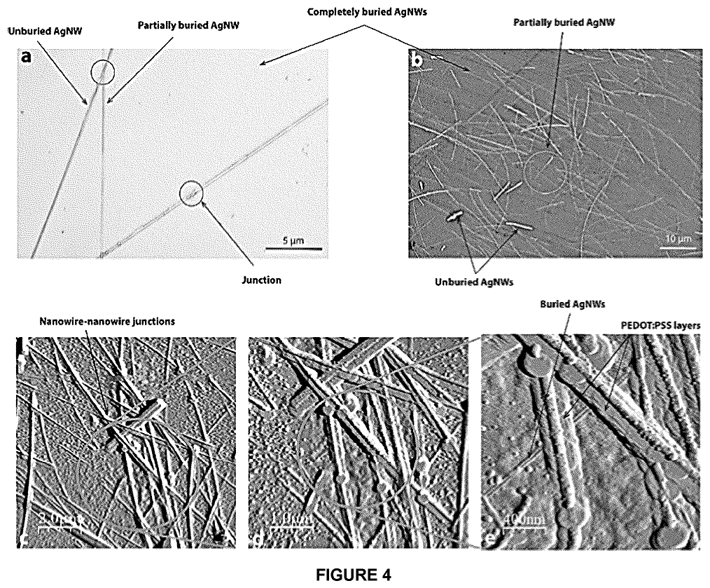

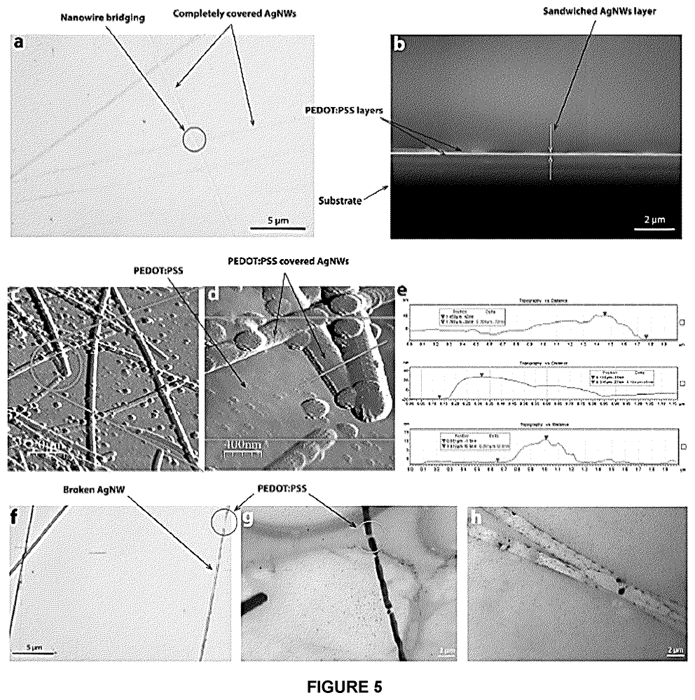

Characterization of the samples. To find an optimum TGH electrode and EMI shield with the highest transparency achievable, different concentrations of AgNWs in ethanol (1, 2, 3, 4, 5, 8, 10, and 12 mg/ml) were prepared, using three types of AgNWs with 30, 60 and 90 nm diameters (labeled as AgNWs-30, AgNWs-60, and AgNWs-90). For all samples, initially, a 20 nm PEDOT:PSS layer was spin coated and annealed at 160° C. for 10 min on the substrates (glass or silicon wafer). Then, the AgNWs were spin coated and annealed at 120° C. for 20 min on the PEDOT:PSS film. Finally, another 20 nm PEDOT:PSS layer was spin coated and annealed on the top of the NWs (FIG. 2a to 2c). The reasons to start with a 20-nm PEDOT:PSS layer deposition on the substrates are: (i) AgNWs could be easily removed, damaged, and brushed away by the next spin coating of PEDOT:PSS layer due to the weak adhesion between AgNWs and the surface,₆₆ and (ii) the layer acts as a conductive sublayer to facilitate the motion of electrons in between AgNWs and the formation of the required percolation. Therefore, the initial 20 nm PEDOT:PSS layer plays a significant role as a medium to make AgNWs stick to the first layer. Adding the second PEDOT:PSS layer on top and covering the AgNWs with a PEDOT:PSS film protects the AgNWs against oxidation, although the developed films would be still sandwiched between two glass substrates for both deicing and EMI shielding applications. Moreover, PEDOT:PSS fills the gaps in between AgNWs junctions via the strong capillary force caused by solvent evaporation,⁶⁸ resulting in the enhancement of conductivity and faster electron transfer through the film (FIG. 2d). This is validated by significant 8 and 5 cm⁻¹ red shift in the main PEDOT:PSS Raman peak of C_{α}=C_{β} band at 1444 cm⁻¹ for PEDOT:PSS/AgNWs and PEDOT:PSS/AgNWs/PEDOT:PSS, respectively (FIG. 3a). The shift is attributed to the change of PEDOT thiophene structure from benzoid to quinoid.₆₉ PEDOT chains locate in between the networks of AgNWs, favoring both inter- and intra-chain charge transport. X-ray diffractometry (XRD) also confirmed the crystallinity of the AgNWs-based hybrid films (FIG. 3b). FIG. 4 depicts the optical microscopy and scanning electron microscopy (SEM) images of PEDOT:PSS and AgNWs. Upon the deposition of AgNWs on PEDOT:PSS followed by the heat treatment at 120° C., some AgNWs were found buried inside the underneath PEDOT:PSS medium either partially or completely and the rest were remained unburied (FIGS. 4a and 4b). This is due to the randomness distribution of NWs over the PEDOT:PSS layer, causing some of them to fall on the top of the other NWs and create numerous NW-NW junctions throughout the film—also confirmed by atomic force microscopy (AFM) images (FIG. 4c to 4e). The unburied NWs reflected more light and appeared brighter inside SEM images (FIG. 4b). After spin coating the second layer of PEDOT:PSS on the top of the AgNWs, all NWs were completely coated with the PEDOT:PSS layers from beneath and top (FIGS. 5a to 5d and 5h). The first reason to add up this second layer of PEDOT:PSS was due to the detection of some NWs breakage after annealing, which was captured by optical microscopy and confirmed by transmission electron microscopy (TEM) images (FIGS. 5f and 5g). Annealing AgNWs after coating them on the initial PEDOT:PSS layer resulted in the breakage of some NWs, owing to their melting. Although the melting point of Ag is about 962° C., the high surface stress derived from its nanostructure form lowers the melting point considerably down to around 85° C.^{70,71} Melting of the NWs has been shown to contribute to the reduction of the contact resistances between them, however, their percolation network would be impacted, leading to the reduction of the conductivity. Increasing the temperature to above 160° C. has been demonstrated to break the percolation network and increase the sheet resistance to the point where it is totally lost at 205° C.⁷² Addition of PEDOT:PSS was intended to fill the gaps between the separated segments within each broken NW (FIGS. 5c and 5h) to sustain the percolation network so that the electrons could tunnel through the gaps rather than any long range hops that require high energy. While the majority of the AgNWs were connected to each other, there still remained a small number of disjointed wires without participating in the transfer of electrons and creating the percolation network.⁷³ The second reason for adding PEDOT:PSS layer on the top of the AgNWs was to create a continuous medium between separated NWs together as well as to the rest of the network so that the conduction channels would be maintained in connection with each other, enhancing the overall conductivity. The third reason for the PEDOT:PSS deposition over AgNWs was to increase the mechanical stability of the underneath NWs from peeling off as numerous studies have reported that their coarse AgNWs coated on bare substrates could be easily removed by adhesion or friction.^{58,73-77} PEDOT:PSS would act as a strong binder between AgNWs, soldering them together and to the underneath ultrathin PEODT:PSS layer. The significance of the initial 20 nm layer deposition of PEDOT:PSS would be recognized again here since it provides a robust anchoring effect between NWs and the substrate. FIG. 5e illustrates the thickness variation of AgNWs after being coated by PEDOT:PSS. The junction region where NWs fall on top of each other presented higher thickness values compared with the partially-buried ones.

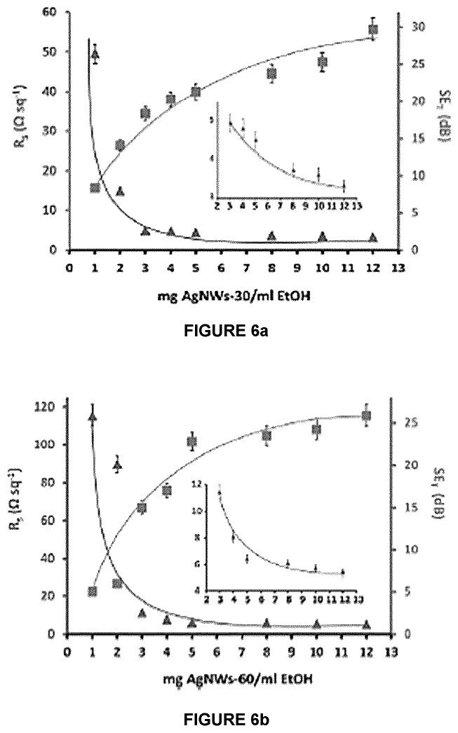

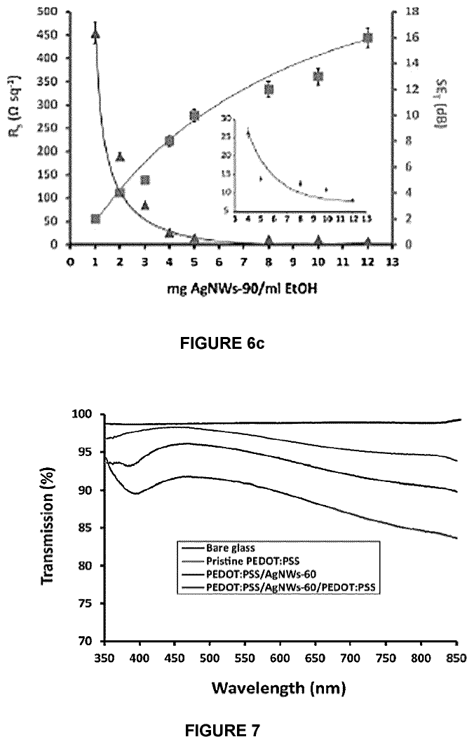

To fabricate a TGH film and an EMI shield that can meet the standards set by the industry such as being cost-effective, lightweight with more than 90% transparency and quick Joule heating response, the ideal AgNWs size, and concentration needed to be evaluated first in terms of sheet resistance, shielding effectiveness and transparency. Therefore, all three types of NWs were assessed at a wide range of concentrations (FIG. 6). For all samples, the sheet resistance (Rₛ) decreased exponentially as the concentration of NWs increased, leading to the enhancement of conductivity and total EMI shielding effectiveness (SE_{T}) accordingly. In fact, the more the number of nanowires is, if distributed uniformly over a surface, the higher the conductivity and SE_{T} values of the surface will be. This is due to the fact that the overall EMI shielding is dependent on the reflection and absorption losses, both correlated with the conductivity of the shield (Eq. S1 to S3). The higher accumulation of NWs on the surface of a film results in more initial reflection of electromagnetic (EM) waves at the interface of the film and air, followed by more absorption of EM waves inside the shield. All AgNWs showed their lowest sheet resistance and highest EMI SE_{T} values at 12 mg/ml concentration. Although the lowest sheet resistance of 3 Ωsq₋₁ and the highest EMI SE_{T} of 30 dB were obtained for the 12 mg/ml AgNWs with 30 nm diameter (AgNWs-30), the poor transmission of 61% at 550 nm—the lowest among all NWs—made us refrain from considering this sample as an ideal TGH or a transparent EMI shield (FIG. 6a). The 2 mg/ml AgNWs-30 with a higher transmission of 95% showed a sheet resistance of 15 Ωsq₋₁ and the lower EMI SE_{T} of 14.1 dB. Next, the AgNWs-60 sample with 12 mg/ml concentration presented the sheet resistance of 5.5 Ωsq₋₁ and the EMI SE_{T} of 26 dB (FIG. 6b). However, the transparency of AgNWs-60 samples with concentrations above 5 mg/ml were less than 90% (88, 86, and 80% for 8, 10 and 12 mg/ml, respectively). Due to the significance of transparency in both targeted applications, we selected the 5 mg/ml sample for the Joule heating test offered the sheet resistance of 6.4 Ωsq₋₁ and the EMI SE_{T} of 23 dB at appreciable transparency of 91% (FIG. 7). Finally, the 12 mg/ml concentration of AgNWs-90 with the transmission of 90% provided a sheet resistance of 8 Ωsq₋₁ and an EMI SE_{T} of 16 dB, persuading us to try this sample for the Joule heating test reluctantly (FIG. 6c). Overall, as the density of NWs increased, both the sheet resistance and transmission of the prepared films decreased. It was also found that the smaller the size of NWs diameter is, the lower the sheet resistance and transparency of the films are, resulting in a higher conductivity and EMI shielding.

Deicing device fabrication. The capability of the two selected samples for Joule heating was evaluated differently from other most routinely performed studies. Except for a few,^{6,78,79} most of the studies for transparent conductive heater electrodes have been testing their fabricated defroster/defogger films under “ambient temperature” inside the laboratory. For this reason, the reported temperature-time graphs reveal that the defrosting/defogging tests started initially at 25° C. or 30° C. temperatures. Frosted samples were first taken out of the fridge and then connected to a power source where the thin film heaters were already exposed to room temperature for several minutes before the defrosting setup could take over as well as during the time when defrosting was in process. The ambient temperature will undeniably contribute a lot to the defrosting mechanism in stark contrast with the actual winter temperature conditions where the defrosting of vehicles must occur inside a subzero temperature. Unfortunately, this type of testing throws a shadow on the reality of the reported response times. One study reported that the defogging of their hybrid film heaters took about 10 min to happen in ambient conditions with no applied potential.₈₀ Another study set up a TGH film-free control experiment beside their hybrid film heater where it took 2 min for defrosting on a glass substrate.₈₁ Most groups used fog, frost or dry ice to test their film heaters Joule heating ability. The removal of fog, frost and dry ice at room temperature is so rapid that it could happen automatically on its own without the need for any power source. We came across only two experiments, performed over ice78 and ice cube.6

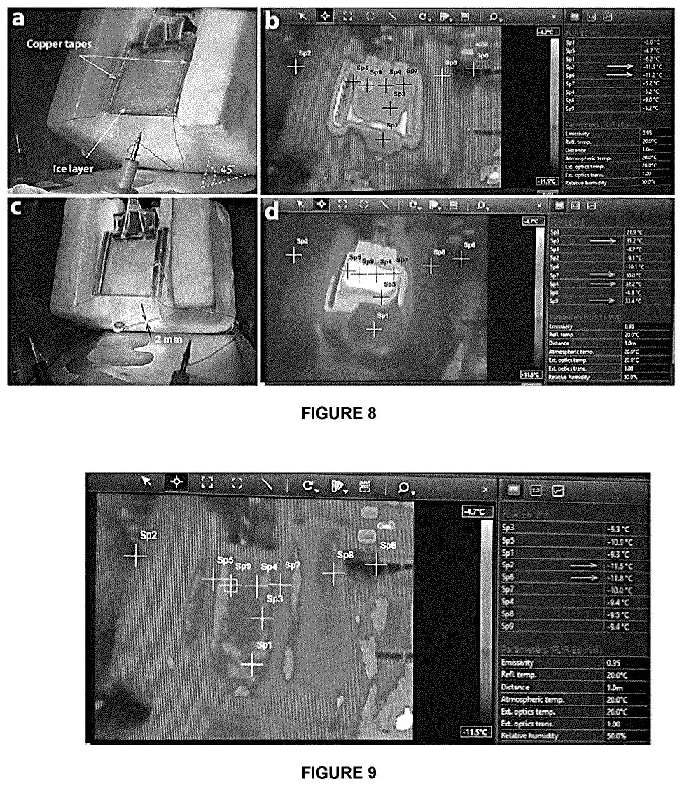

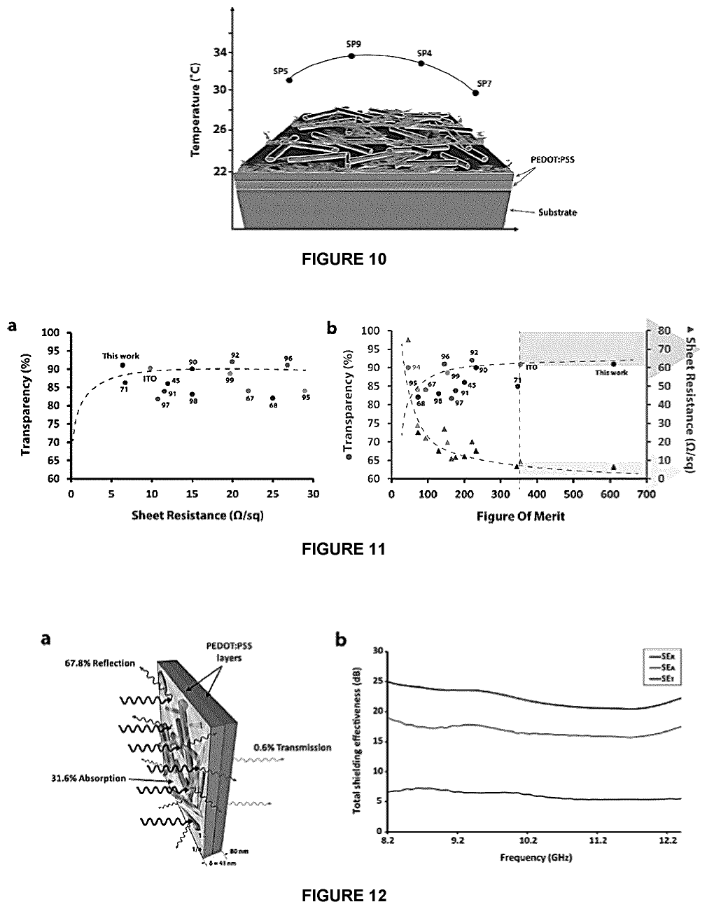

FIG. 8a demonstrates the deicing apparatus setup inside an environmental chamber where the temperature was maintained at −10° C. to mimic winter weather conditions during the deicing (details explained in the Experimental Section). Initial deicing test of sandwiched PEDOT:PSS/AgNWs-90/PEDOT:PSS hybrid thin film between two ˜2.5 mm glass substrates upon applying 12 V power resulted in the immediate melting of the 2 mm ice layer bottom part on the glass. However, the deicing slowed down as time passed and did not proceed at the earlier pace. After 10 min, the experiment was stopped due to the longevity of deicing. Next, the PEDOT:PSS/AgNWs-60/PEDOT:PSS thin film sample was tested for deicing under the same conditions. As soon as the 12 V power was applied, deicing started again from the lower part of the glass (FIG. 8b) and continued to engage the whole substrate in less than a minute. Due to the clipping of the ice to the glass, another minute was required for the whole 2 mm layer to drop off the substrate (FIG. 8c). This is while in a vehicle the ice slides down due to gravity or wipers can remove the ice as soon as the thawing starts underneath the windshield. It is noticeable that the temperature increased sharply from ˜−12° C. before the application of the voltage (FIG. 9) to a maximum of 33.4° C. in less than 2 min (FIG. 8d). After the ice layer drop-off, the average temperature on the upper exterior glass was measured to be 32±2° C. (FIG. 8d). It is highly noteworthy to remind that the achieved 44±2° C. temperature elevation is so appreciable and considerable when noticing that, unlike other studies, the immediate deicing occurred while the surrounding temperature was maintained at −10° C. The condition of deicing under the impact of subzero temperature is quite different from the ones starting at room temperatures of 25° C. and 30° C. The ambient temperature contributes significantly to both the speed and temperature of the defrosting/defogging experiments. The freezing chamber temperature acts as a resistive factor against the temperature rise. The uniformity of the temperature profile, as observed in FIG. 8d, is measured to be only with 3.4° C. deviations across the thin film heater at SP5, 9, 4, and 7 spots (FIG. 10).

In comparison with the commercial ITO₈₂ and other proposed studies to date, which used PEDOT:PSS and AgNWs, the proposed TGH apparatus offered the lowest sheet resistance while maintaining a >90% transparency (FIG. 11a). The high figure of merit (FoM) of 610 (Eq. S4) also supported the competency of the developed hybrid film compared to the commercial ITO and previously reported transparent conducting electrodes (TCEs). As FIG. 11b indicates, a desirable transparent conductor would be the one with >90% optical transmission as well as <10 Ωsq⁻¹ sheet resistance, which yields FoM >350. In a broader spectrum, the designed hybrid film provided more advantages over existing developed technologies that have used AgNWs alone or in combination with other conductive materials. To name a few: (i) the fabrication method is very simple and cost-efficient without common complexities of most other techniques, although, for highly uniform coating, printing methods such as rod-coating or even high-tech inkjet lithography can be applied as a tradeoff for the cost; (ii) the use of solvents, binders, film transferring and pressing against substrate is not required; (iii) its >90% transparency outruns currently-made lower transmission TGHs that are proposed to be applied as tinted windows, (iv) no hot spots were observed during deicing and (v) unlike other methods, which require placing the TGH on the exterior side of the substrate in direct contact with frost and ice; thus, requiring a protective layer and encapsulation, our sandwich design of the hybrid film between two ˜2.5 mm glass substrates makes our developed film protected against scratching, harsh weather conditions and oxidation as well as increasing its life span. One significant failure with metal grids, nanowires, and meshes is that they tend to become oxidized in outdoor conditions and are chemically unstable which results in the deterioration of their conductivity.⁸³⁻⁸⁵ To avoid the oxidation issue, studies developed graphene-based protective layers to act as passivation layers over the AgNWs,⁸⁶⁻⁸⁹ increasing the number of processing steps, cost, and the loss of transmittance.

EMI shielding effectiveness. As observed in FIG. 6a, the PEDOT:PSS/AgNWs-30/PEDOT:PSS with AgNWs concentration of 12 mg/ml presented the highest EMI SE_{T} of 30 dB for a ˜50 nm film, which is a record value on its own, considering its thickness compared with other proposed micron- or millimeter-thick nanocomposites to date, however, the optical transparency was as low as 61%—not apt for our purpose. The reason behind such a low transmission for a film this thin may lie beneath the diameter size of the NWs, which brought them together and led to their aggregation. As we found earlier that the sheet resistance of AgNWs network would decrease upon reducing their diameter; yet, it can be also concluded that NWs with diameters lower than ˜60 nm will have lower optical transparency. In our previous study, we developed a new class of filler-free EMI shields that could offer 15 dB shielding in the X band frequency range (8.2-12.4 GHz) with 97.1% transparency for a ˜50 nm ultrathin film._{[ref]} The newly-developed ˜80 nm PEDOT:PSS/AgNWs-60/PEDOT:PSS nanocomposite with AgNWs concentration of 5 mg/ml offered an outstanding EMI SE_{T} of 23 dB in the X band frequency range with a high optical transparency of 91%. Such a high EMI shielding value roots in the achieved low sheet resistance of 6.4 Ωsq₋₁ for the developed ultrathin film on the interface of the shield and air as the first point of interaction with EM waves. The combination of AgNWs and PEDOT:PSS provided abundant free charge carriers at the surface, resulting in 0.6% transmittance of EM waves and meeting the requirement for industrial applications in which only 1% of the EM waves are allowed to transmit (FIG. 12a).₉₀ The amount of reflection and absorption losses (Eq. S16 and S17) were measured to be 6 and 17 dB, respectively (FIG. 12b). The high density of the charge carriers at the surface that could reflect ˜70% of the incident EM waves before any absorption would occur inside the shield resulted in the calculated skin depth (δ) of 40.8 nm (Eq. S3)—almost half of the film thickness (FIG. 12a).

### CONCLUSION

In summary, a highly transparent hybrid thin film electrode, consisting of a conductive polymer and AgNWs, was fabricated in a novel layer-by-layer assembly without requiring vacuum, pressing or high temperature processing. The ˜80 nm hybrid film offered the sheet resistance as low as 6.4 Ωsq-1, transparency of 91% and total EMI shielding of 23 dB, promising for the Joule heating, as a replacement for the conventional ITO electrodes, and a substitute for thicker and heavier EMI shields with lower transparency. As a TGH with the FoM of 610, it presented an effective deicing of 2 mm ice under a sub-zero temperature of −10° C. in less than a minute. Our sandwich technique circumvented the frequently reported issues of other proposed electrodes, such as oxidation, scratching, and mechanical failure in harsh weather conditions. These achieved unique properties in addition to the low cost and environmentally friendly aspects of the film all outperform the typical ITO and other metal- and carbon-based counterparts to date. Furthermore, the apparatus can be easily scaled up for mass production on larger flat or curved surfaces, owing to its low-temperature and simple fabrication method. The new and facile production approach along with the remarkable performance of the device offer new routes for manufacturing high-performance TGHs for different applications.

### Experimental Section

Sample preparation. AgNWs (ACS Material) were purchased in three diameters: 30 nm (100-200 μm length), 60 nm (20-60 μm length), and 90 nm (20-30 μm length) all in ethanol. PEDOT:PSS dispersion in water (Clevios PH1000, Heraeus) with 1-1.3 wt % concentration and 1:2.5 ratio was ultrasonicated for 15 min and filtered, using a 0.45 μm syringe filter (Sterlitech). Four types of substrates were used: (i) double-sided polished 2×2 cm² silicon wafers (E&M Corp. Ltd.), (ii) 2.5×2.5 cm², (iii) 5×5 cm², and (iv) 5×1 cm² glass substrates, all cleaned by acetone, DI water, and isopropanol, respectively. The samples coated on silicon wafers were used for FTIR, Raman, XRD, CS-AFM, and SEM characterizations. The samples deposited on the 2.5×2.5 cm² glass substrates were used for optical microscopy, electrical conductivity, and EMI shielding measurements. The samples coated on the 5×5 cm² glass substrates were used for the deicing experiment and the samples deposited on the 5×1 cm² glass substrates were used for UV-Vis measurements. The thickness of all glass substrates was ˜2.5 mm. After drying, all substrates were UV-Ozone (PSDP Pro, Novascan Technologies Inc.) treated for 30 min. Each layer was coated by spin coating (WS-650-23, Laurell Technologies Corporation). The spin coater speed was adjusted to 7000 rpm for 1 min and 5000 rpm for 30 s to produce 20 and 40 nm of PEDOT:PSS films, respectively, and 5000 rpm for 30 s to deposit AgNWs. PEDOT:PSS layers and AgNWs layer were annealed inside a vacuum oven at 160° C. for 10 min and 120° C. for 20 min, respectively, to remove any residual water and solvent. The deicing test was performed inside an environmental testing chamber (MicroClimate, Cincinnati Sub-Zero). The 12 V voltage was applied using a Keithley 2400 digital source meter. Temperatures of different spots on the substrate were scanned and recorded by a thermal imaging camera (FLIR E6, ITM Instruments).

Characterization. The thickness of the films was measured by profiling on 4 spots and fitting a B-Spline model over the Cauchy layer after obtaining a reasonable mean square error using variable-angle spectroscopic ellipsometer (J. A. Woollam-M2000). AFM (N9410S, 5500 Keysight Technologies Inc.) data acquisition was conducted using a PtSi coated silicon cantilever in contact mode with a resonance frequency of 160 kHz. AFM scan speed of 0.3 line per second with 256 points per line, varying based on the feature sizes, was used. The linear four-point probe (Loresta GP, MCP-T610, Mitsubishi Chemical Co.) technique was applied to measure the conductivity of the films at an applied voltage of 10 V. Raman spectroscopy (WITec alpha 300 R) was performed from 0 to 3700 cm₋₁ on a confocal Raman microscope using a 532 nm laser with the 30-60 s typical integration time of acquisition. XRD (Rigaku ULTIMA III) patterns were obtained on PEDOT:PSS untreated and treated films (<1 μm) in conventional theta/2theta geometry between 3° and 80°, with Cu-K α radiation (λ=1.5406 Å) at 40 kV and 100 mA. Transmission spectra were measured at the typical 550 nm wavelength using a UV-Vis spectrophotometer (UV-2600, Shimadzu). The EMI shielding absorption and reflection signals, as well as real and imaginary values of dielectric constants, were measured over the X-band (8.2-12.4 GHz) frequency by sandwiching the samples between two X-band waveguide sections connected to separate ports of an Agilent Vector Network Analyzer (E 5071C, ENA series 300 kHz to 20 GHz). A clean bare glass substrate was used as a baseline for transparency and shielding measurements. The microstructural features of the samples were characterized by (i) optical inverted microscopy (Nikon Eclipse Ti2) over glass substrates, using the iDS uEye camera, (ii) SEM (FEI XL30) with extra high definition mode (11.6 megapixels), and accelerating voltage adjustable between 0.5 kV and 30 kV to optimize imaging conditions to the sample after fracturing 16 the silicon wafers in liquid nitrogen and (iii) TEM (Hitachi H-7650) at 120 kV acceleration voltage with 16 megapixels camera, using 300-mesh Cu TEM grids with a two-layer graphene film on a lacey carbon film as a substrate.

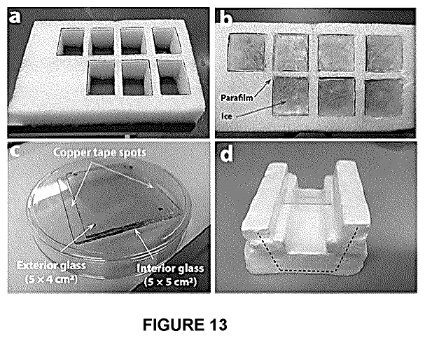

Deicing test setup. Initially, a thick sheet of Styrofoam was cut to hold the 5×4 cm² glass substrates (FIG. 13a). These glass substrates were meant to represent the exterior glass of a vehicle windshield. They were pushed down enough inside the cuts so that water could completely cover and stay all over the surface of the substrates. A layer of Parafilm was used for each glass to cover the backside of the substrates in order to avoid water slipping to the rear side of the glass. After leaving the Styrofoam sheet inside a freezer, 2 mm ice was formed on the top of the substrates (FIG. 13b). The hybrid films of PEDOT:PSS/AgNWs-60/PEDOT:PSS and PEDOT:PSS/AgNWs-90/PEDOT:PSS with 5 and 12 mg/ml of AgNWs concentration, respectively, were coated on separate 5×5 cm² glass substrates, representing the interior glass of a vehicle windshield. The reason behind designing the interior glass size bigger than the exterior one was to make enough space for the conductive copper tapes to lay down on the hybrid films (FIG. 13c). A Styrofoam V-shaped trench drain covered with Parafilm was built to hold both glass substrates during the deicing test (FIG. 13d). Before transferring the ice-covered exterior glass substrates from the freezer to the top of the interior ones, copper tapes were placed on the wires that were already in contact with the hybrid films coated on the interior 5×5 cm² glass substrates. The wires were then connected to the power source where the voltage was set to 12 V, similar to an automobile battery. The whole setup, including the power source wires, the sample holder, and the interior substrates coated with hybrid films and copper tapes on the edges were placed inside an environmental testing chamber at −10° C. to mimic winter weather conditions. Then, the ice-coated 5×4 cm² glass substrates were immediately transferred to the chamber after removing the Parafilm layers and were simply attached to the underneath 5×5 cm² glass substrates, using a metal clip that was insulated from touching the ice on the top and glass at the bottom by Parafilm wraps. With this setup, the PEDOT:PSS/AgNWs/PEDOT:PSS hybrid thin films were sandwiched between two glass substrates. The attachment of ˜2.5 mm thick glass substrates together formed a ˜5 mm windshield-like glass that was intentionally placed 45° angled inside the chamber, as in most vehicles. The setup was left for extra time inside the chamber in order to let the temperature reach back to −10° C. again. To monitor the temperature during deicing, a thermal forward-looking infrared (FLIR) imaging camera was placed in front of the sample holder inside the chamber with 9 different spots (SP) under continuous scanning (FIG. 9). The deicing procedure was recorded from outside of the chamber window, using a regular iPhone 6.

### REFERENCES

(1) Wu, H.; Hu, L.; Carney, T.; Ruan, Z.; Kong, D.; Yu, Z.; Yao, Y.; Cha, J. J.; Zhu, J.; Fan, S.; et al. Low Reflectivity and High Flexibility of Tin-Doped Indium Oxide Nanofiber Transparent Electrodes. J. Am. Chem. Soc. 2011, 133 (1), 27-29. https://doi.org/10.1021/ja109228e.
(2) Zhou, N.; Buchholz, D. B.; Zhu, G.; Yu, X.; Lin, H.; Facchetti, A.; Marks, T. J.; Chang, R. P. H. Ultraflexible Polymer Solar Cells Using Amorphous Zinc-Indium-Tin Oxide Transparent Electrodes. Adv. Mater. 2014, 26 (7), 1098-1104. https://doi.org/10.1002/adma.201302303.
(3) Li, S.; Tian, M.; Gao, Q.; Wang, M.; Li, T.; Hu, Q.; Li, X.; Wu, Y. Nanometre-Thin Indium Tin Oxide for Advanced High-Performance Electronics. Nat. Mater. 2019, 18 (10), 1091-1097. 17 https://doi.org/10.1038/s41563-019-0455-8.
(4) Zhao, X.; Tan, Z. K. Large-Area near-Infrared Perovskite Light-Emitting Diodes. Nat. Photonics 2019. https://doi.org/10.1038/s41566-019-0559-3.
(5) Chavan, S.; Foulkes, T.; Gurumukhi, Y.; Boyina, K.; Rabbi, K. F.; Miljkovic, N. Pulse Interfacial Defrosting. Appl. Phys. Lett. 2019, 115 (7). https://doi.org/10.1063/1.5113845.
(6) Lee, S. M.; Lee, J. H.; Bak, S.; Lee, K.; Li, Y.; Lee, H. Hybrid Windshield-Glass Heater for Commercial Vehicles Fabricated via Enhanced Electrostatic Interactions among a Substrate, Silver Nanowires, and an over-Coating Layer. Nano Res. 2015, 8 (6), 1882-1892. https://doi.org/10.1007/s12274-014-0696-4.
(7) Kang, T. J.; Kim, T.; Seo, S. M.; Park, Y. J.; Kim, Y. H. Thickness-Dependent Thermal Resistance of a Transparent Glass Heater with a Single-Walled Carbon Nanotube Coating. Carbon N. Y. 2011, 49 (4), 1087-1093. https://doi.org/10.1016/j.carbon.2010.11.012.
(8) Gupta, R.; Rao, K. D. M.; Kiruthika, S.; Kulkarni, G. U. Visibly Transparent Heaters. ACS Appl. Mater. Interfaces 2016, acsami.5b11026. https://doi.org/10.1021/acsami.5b11026.
(9) Hong, S.; Lee, H.; Lee, J.; Kwon, J.; Han, S.; Suh, Y. D.; Cho, H.; Shin, J.; Yeo, J.; Ko, S. H. Highly Stretchable and Transparent Metal Nanowire Heater for Wearable Electronics Applications. Adv. Mater. 2015, 27 (32), 4744-4751. https://doi.org/10.1002/adma.201500917.
(10) Maniyara, R. A.; Mkhitaryan, V. K.; Chen, T. L.; Ghosh, D. S.; Pruneri, V. An Antireflection Transparent Conductor with Ultralow Optical Loss and High Electrical Conductance. Nat. Commun. 2016, No. 7, 13771. https://doi.org/10.1109/cleoe-eqec.2017.8087137.
(11) Yonglai, Y.; Mool, C. G.; Kenneth, L. D.; Roland, W. L. Novel Carbon Nanotube-Polystyrene Foam Composites for Electromagnetic Interference Shielding. Nano Lett. 2005, 5. https://doi.org/10.1021/n1051375r.
(12) Ma, L.; Lu, Z.; Tan, J.; Liu, J.; Ding, X.; Black, N.; Li, T.; Gallop, J.; Hao, L. Transparent Conducting Graphene Hybrid Films to Improve Electromagnetic Interference (EMI) Shielding Performance of Graphene. ACS Appl. Mater. Interfaces 2017, 9 (39), 34221-34229. https://doi.org/10.1021/acsami.7b09372.
(13) Han, Y.; Lin, J.; Liu, Y.; Fu, H.; Ma, Y.; Jin, P.; Tan, J. Crackle Template Based Metallic Mesh with Highly Homogeneous Light Transmission for High-Performance Transparent EMI Shielding. Sci. Rep. 2016, 6 (January), 1-11. https://doi.org/10.1038/srep25601.
(14) Ren, P.-G.; Yan, D.-X.; Pang, H.; Li, Z.-M.; Fu, Q.; Yang, M.-B. Efficient Electromagnetic Interference Shielding of Lightweight Graphene/Polystyrene Composite. J. Mater. Chem. 2012, 22 (36), 18772. https://doi.org/10.1039/c2jm32692b.
(15) Kim, A.; Won, Y.; Woo, K.; Jeong, S.; Moon, J. All-Solution-Processed Indium-Free Transparent Composite Electrodes Based on Ag Nanowire and Metal Oxide for Thin-Film Solar Cells. Adv. Funct. Mater. 2014. https://doi.org/10.1002/adfm.201303518.
(16) Hagendorfer, H.; Lienau, K.; Nishiwaki, S.; Fella, C. M.; Kranz, L.; Uhl, A. R.; Jaeger, D.; Luo, L.; Gretener, C.; Buecheler, S.; et al. Highly Transparent and Conductive ZnO: Al Thin Films from a Low Temperature Aqueous Solution Approach. Adv. Mater. 2014. https://doi.org/10.1002/adma.201303186. 18 (17) Wang, B. W.; Jiang, S.; Zhu, Q. B.; Sun, Y.; Luan, J.; Hou, P. X.; Qiu, S.; Li, Q. W.; Liu, C.; Sun, D. M.; et al. Continuous Fabrication of Meter-Scale Single-Wall Carbon Nanotube Films and Their Use in Flexible and Transparent Integrated Circuits. Adv. Mater. 2018. https://doi.org/10.1002/adma.201802057.
(18) Geng, H.-Z.; Kim, K. K.; So, K. P.; Lee, Y. S. H.; Chang, Y.; Lee, Y. S. H. Effect of Acid Treatment on Carbon Nanotube-Based Flexible Transparent Conducting Films. J. Am. Chem. Soc. 2007, 129 (25), 7758-7759. https://doi.org/10.1021/ja0722224.
(19) Kim, K. S. K. S.; Zhao, Y.; Jang, H.; Lee, S. Y.; Kim, J. M.; Kim, K. S. K. S.; Ahn, J.-H.; Kim, P.; Choi, J.-Y.; Hong, B. H. Large-Scale Pattern Growth of Graphene Films for Stretchable Transparent Electrodes. Nature 2009, 457 (7230), 706-710. https://doi.org/10.1038/nature07719.
(20) Han, J.; Lee, J. Y.; Lee, J.; Yeo, J. S. Highly Stretchable and Reliable, Transparent and Conductive Entangled Graphene Mesh Networks. Adv. Mater. 2018. https://doi.org/10.1002/adma.201704626.
(21) Bae, S.; Kim, H.; Lee, Y.; Xu, X.; Park, J.-S.; Zheng, Y.; Balakrishnan, J.; Lei, T.; Ri Kim, H.; Song, Y. II; et al. Roll-to-Roll Production of 30-Inch Graphene Films for Transparent Electrodes. Nat. Nanotechnol. 2010, 5 (8), 574-578. https://doi.org/10.1038/nnano.2010.132.
(22) Ye, S.; Rathmell, A. R.; Chen, Z.; Stewart, I. E.; Wiley, B. J. Metal Nanowire Networks: The next Generation of Transparent Conductors. Adv. Mater. 2014, 26 (39), 6670-6687. https://doi.org/10.1002/adma.201402710.
(23) Zhang, Y.; Guo, J.; Xu, D.; Sun, Y.; Yan, F. Synthesis of Ultralong Copper Nanowires for High-Performance Flexible Transparent Conductive Electrodes: The Effects of Polyhydric Alcohols. Langmuir 2018. https://doi.org/10.1021/acs.langmuir.8b00344.
(24) Soltanian, S.; Rahmanian, R.; Gholamkhass, B.; Kiasari, N. M.; Ko, F.; Servati, P. Highly Stretchable, Sparse, Metallized Nanofiber Webs as Thin, Transferrable Transparent Conductors. Adv. Energy Mater. 2013, 3 (10), 1332-1337. https://doi.org/10.1002/aenm.201300193.
(25) Zhu, X.; Xu, Q.; Li, H.; Liu, M.; Li, Z.; Yang, K.; Zhao, J.; Qian, L.; Peng, Z.; Zhang, G.; et al. Fabrication of High-Performance Silver Mesh for Transparent Glass Heaters via Electric-Field-Driven Microscale 3D Printing and UV-Assisted Microtransfer. Adv. Mater. 2019. https://doi.org/10.1002/adma.201902479.
(26) Lee, J. Y.; Connor, S. T.; Cui, Y.; Peumans, P. Solution-Processed Metal Nanowire Mesh Transparent Electrodes. Nano Lett. 2008. https://doi.org/10.1021/n1073296g.
(27) Design, R.; Films, H. G.; Electrodes, H. T. Rational Design of Hybrid Graphene Films for High-Performance. ACS Nano 2011.
(28) Kim, S. H.; Song, W.; Jung, M. W.; Kang, M. A.; Kim, K.; Chang, S. J.; Lee, S. S.; Lim, J.; Hwang, J.; Myung, S.; et al. Carbon Nanotube and Graphene Hybrid Thin Film for Transparent Electrodes and Field Effect Transistors. Adv. Mater. 2014. https://doi.org/10.1002/adma.201400463.
(29) Scardaci, V.; Coull, R.; Lyons, P. E.; Rickard, D.; Coleman, J. N. Spray Deposition of Highly Transparent, Low-Resistance Networks of Silver Nanowires over Large Areas. Small 2011, 7 (18), 2621-2628. https://doi.org/10.1002/smlI.201100647.
(30) Kumar, A.; Zhou, C. The Race to Replace Tin-Doped Indium Oxide: Which Material Will Win? ACS 19 Nano 2010, 4 (1), 11-14. https://doi.org/10.1021/nn901903b.
(31) De, S.; Lyons, P. E.; Sorel, S.; Doherty, E. M.; King, P. J.; Blau, W. J.; Nirmalraj, P. N.; Boland, J. J.; Scardaci, V.; Joimel, J.; et al. Transparent, Flexible, and Highly Conductive Thin Films Based on Polymer-Nanotube Composites. ACS Nano 2009, 3 (3), 714-720. https://doi.org/10.1021/nn800858w.
(32) Tung, V. C.; Chen, L. M.; Allen, M. J.; Wassei, J. K.; Nelson, K.; Kaner, R. B.; Yang, Y. Low-Temperature Solution Processing of Graphene-Carbon Nanotube Hybrid Materials for High-Performance Transparent Conductors. Nano Lett. 2009, 9 (5), 1949-1955. https://doi.org/10.1021/n19001525.
(33) Forrest, S. R. The Path to Ubiquitous and Low-Cost Organic Electronic Appliances on Plastic. Nature 2004, 428 (6986), 911-918. https://doi.org/10.1038/nature02498.
(34) Hecht, D. S.; Hu, L.; Irvin, G. Emerging Transparent Electrodes Based on Thin Films of Carbon Nanotubes, Graphene, and Metallic Nanostructures. Adv. Mater. 2011, 23 (13), 1482-1513. https://doi.org/10.1002/adma.201003188.
(35) Celle, C.; Mayousse, C.; Moreau, E.; Basti, H.; Carella, A. Highly Flexible Transparent Film Heaters Based on Random Networks of Silver Nanowires. Nano Res. 2012, 5 (6), 427-433. https://doi.org/10.1007/s12274-012-0225-2.
(36) Sui, D.; Huang, Y.; Huang, L.; Liang, J.; Ma, Y.; Chen, Y. Flexible and Transparent Electrothermal Film Heaters Based on Graphene Materials. Small 2011, 7 (22), 3186-3192. https://doi.org/10.1002/smll.201101305.
(37) Stahl, H.; Appenzeller, J.; Lengeler, B.; Martel, R.; Avouris, P. Investigation of the Inter-Tube Coupling in Single-Wall Nanotube Ropes. Mater. Sci. Eng. C 2001, 15 (1-2), 291-294. https://doi.org/10.1016/S0928-4931(01)00229-6.
(38) Lee, J. Y.; Connor, S. T.; Cui, Y.; Peumans, P. Solution-Processed Metal Nanowire Mesh Transparent Electrodes. Nano Lett. 2008, 8 (2), 689-692. https://doi.org/10.1021/n1073296g.
(39) Coleman, J. N.; De, S. Unknown-Unknown-2010—Are There Fundamental Limitations on the Sheet Resistance and Transmittance of Thin Graphene Films.Pdf.Pdf.Pdf. ACS Nano 2010, 4 (5), 2713-2720.
(40) Gordon, R. G. C Riteria for Choosing Transparent Conductors. History 2000, No. August, 52-57.
(41) Kim, T.; Kim, Y. W.; Lee, H. S.; Kim, H.; Yang, W. S.; Suh, K. S. Uniformly Interconnected Silver-Nanowire Networks for Transparent Film Heaters. Adv. Funct. Mater. 2013, 23 (10), 1250-1255. https://doi.org/10.1002/adfm.201202013.
(42) King, P. J.; Higgins, T. M.; De, S.; Nicoloso, N.; Coleman, J. N.; Al, K. E. T. Percolation E Ff Ects in Supercapacitors with Thin, Transparent Carbon Nanotube Electrodes. 2012, No. 2, 1732-1741.
(43) Mutiso, R. M.; Sherrott, M. C.; Rathmell, A. R.; Wiley, B. J.; Winey, K. I. Integrating Simulations and Experiments to Predict Sheet Resistance and Optical Transmittance in Nanowire Films for Transparent Conductors. ACS Nano 2013, 7 (9), 7654-7663. https://doi.org/10.1021/nn403324t.
(44) Garnett, E. C.; Cai, W.; Cha, J. J.; Mahmood, F.; Connor, S. T.; Greyson Christoforo, M.; Cui, Y.; McGehee, M. D.; Brongersma, M. L. Self-Limited Plasmonic Welding of Silver Nanowire Junctions. 20 Nat. Mater. 2012, 11 (3), 241-249. https://doi.org/10.1038/nmat3238.
(45) Gaynor, W.; Burkhard, G. F.; McGehee, M. D.; Peumans, P. Smooth Nanowire/Polymer Composite Transparent Electrodes. Adv. Mater. 2011, 23 (26), 2905-2910. https://doi.org/10.1002/adma.201100566.
(46) Zilberberg, K.; Gasse, F.; Pagui, R.; Polywka, A.; Behrendt, A.; Trost, S.; Heiderhoff, R.; Görrn, P.; Riedl, T. Highly Robust Indium-Free Transparent Conductive Electrodes Based on Composites of Silver Nanowires and Conductive Metal Oxides. Adv. Funct. Mater. 2014, 24 (12), 1671-1678. https://doi.org/10.1002/adfm.201303108.
(47) Cai, G.; Darmawan, P.; Cui, M.; Wang, J.; Chen, J.; Magdassi, S.; Lee, P. S. Highly Stable Transparent Conductive Silver Grid/PEDOT:PSS Electrodes for Integrated Bifunctional Flexible Electrochromic Supercapacitors. Adv. Energy Mater. 2016, 6 (4), 1-8. https://doi.org/10.1002/aenm.201501882.
(48) Stahlmecke, B.; Meyer Zu Heringdorf, F. J.; Chelaru, L. I.; Horn-Von Hoegen, M.; Dumpich, G.; Roos, K. R. Electromigration in Self-Organized Single-Crystalline Silver Nanowires. Appl. Phys. Lett. 2006, 88 (5), 1-3. https://doi.org/10.1063/1.2172012.
(49) Zhao, J.; Sun, H.; Dai, S.; Wang, Y.; Zhu, J. Electrical Breakdown of Nanowires. Nano Lett. 2011, 11 (11), 4647-4651. https://doi.org/10.1021/nl202160c.
(50) Huang, Q.; Lilley, C. M.; Divan, R. An in Situ Investigation of Electromigration in Cu Nanowires. Nanotechnology 2009, 20 (7), 075706. https://doi.org/l0.1088/0957-4484/20/7/075706.
(51) Elechiguerra, J. L.; Larios-Lopez, L.; Liu, C.; Garcia-Gutierrez, D.; Camacho-Bragado, A.; Yacaman, M. J. Corrosion at the Nanoscale: The Case of Silver Nanowires and Nanoparticles. Chem. Mater. 2005, 17 (24), 6042-6052. https://doi.org/10.1021/cm051532n.
(52) Galagan, Y.; Zimmermann, B.; Coenen, E. W. C.; Jorgensen, M.; Tanenbaum, D. M.; Krebs, F. C.; Gorter, H.; Sabik, S.; Slooff, L. H.; Veenstra, S. C.; et al. Current Collecting Grids for ITO-Free Solar Cells. Adv. Energy Mater. 2012, 2 (1), 103-110. https://doi.org/10.1002/aenm.201100552.
(53) Gupta, R.; Rao, K. D. M.; Srivastava, K.; Kumar, A.; Kiruthika, S.; Kulkarni, G. U. Spray Coating of Crack Templates for the Fabrication of Transparent Conductors and Heaters on Flat and Curved Surfaces. ACS Appl. Mater. Interfaces 2014, 6 (16), 13688-13696. https://doi.org/10.1021/am503154z.
(54) Singh, K. B.; Tirumkudulu, M. S. Cracking in Drying Colloidal Films. Phys. Rev. Lett. 2007, 98 (21), 218302. https://doi.org/10.1103/PhysRevLett.98.218302.
(55) Arjmand, M.; Chizari, K.; Krause, B.; Pötschke, P.; Sundararaj, U. Effect of Synthesis Catalyst on Structure of Nitrogen-Doped Carbon Nanotubes and Electrical Conductivity and Electromagnetic Interference Shielding of Their Polymeric Nanocomposites. Carbon N. Y. 2016. https://doi.org/10.1016/j.carbon.2015.11.024.
(56) Colegrove, J. ITO Replacement—Non-ITO Transparent Conductor Technologies, Supply Chain and Market Forecast; Santa Clara, CA, US, 2019.
(57) Werner, K. Silver Nanowires Get Large. Display Daily. 2015.
(58) Hu, L.; Kim, H. S.; Lee, J. Y.; Peumans, P.; Cui, Y. Scalable Coating and Properties of Transparent, 21 Flexible, Silver Nanowire Electrodes. ACS Nano 2010, 4 (5), 2955-2963. https://doi.org/10.1021/nn1005232.
(59) Gaynor, W.; Lee, J. Y.; Peumans, P. Fully Solution-Processed Inverted Polymer Solar Cells with Laminated Nanowire Electrodes. ACS Nano 2010. https://doi.org/10.1021/nn900758e.
(60) Lee, J. Y.; Connor, S. T.; Cui, Y.; Peumans, P. Semitransparent Organic Photovoltaic Cells with Laminated Top Electrode. Nano Lett. 2010. https://doi.org/10.1021/n1903892x.
(61) De, S.; Higgins, T. M.; Lyons, P. E.; Doherty, E. M.; Nirmalraj, P. N.; Blau, W. J.; Boland, J. J.; Coleman, J. N. Silver Nanowire Networks as Flexible, Transparent, Conducting Films: Extremely High DC to Optical Conductivity Ratios. ACS Nano 2009. https://doi.org/10.1021/nn900348c.
(62) Madaria, A. R.; Kumar, A.; Ishikawa, F. N.; Zhou, C. Uniform, Highly Conductive, and Patterned Transparent Films of a Percolating Silver Nanowire Network on Rigid and Flexible Substrates Using a Dry Transfer Technique. Nano Res. 2010. https://doi.org/10.1007/s12274-010-0017-5.
(63) Liu, C. H.; Yu, X. Silver Nanowire-Based Transparent, Flexible, and Conductive Thin Film. Nanoscale Res. Lett. 2011. https://doi.org/10.1186/1556-276X-6-75.
(64) Zeng, X. Y.; Zhang, Q. K.; Yu, R. M.; Lu, C. Z. A New Transparent Conductor: Silver Nanowire Film Buried at the Surface of a Transparent Polymer. Adv. Mater. 2010. https://doi.org/10.1002/adma.201001811.
(65) Yu, Z.; Zhang, Q.; Li, L.; Chen, Q.; Niu, X.; Liu, J.; Pei, Q. Highly Flexible Silver Nanowire Electrodes for Shape-Memory Polymer Light-Emitting Diodes. Adv. Mater. 2011. https://doi.org/10.1002/adma.201003398.
(66) Lee, J.; Lee, P.; Lee, H.; Lee, D.; Lee, S. S.; Ko, S. H. Very Long Ag Nanowire Synthesis and Its Application in a Highly Transparent, Conductive and Flexible Metal Electrode Touch Panel. Nanoscale 2012, 4 (20), 6408-6414. https://doi.org/10.1039/c2nr31254a.
(67) Qingqing, Y.; Jinliang, Y.; Delan, M. Transparent and Conductive PEDOT:PSS/AgNW/PEDOT:PSS Hybrid Films Pre-Pared by Spin-Coating at Room Temperature. J. Semicond. 2015, 36 (12), 12-16. https://doi.org/10.1088/1674-4926/36/12/123005.
(68) Lee, J.; Lee, P.; Lee, H. B.; Hong, S.; Lee, I.; Yeo, J.; Lee, S. S.; Kim, T. S.; Lee, D.; Ko, S. H. Room-Temperature Nanosoldering of a Very Long Metal Nanowire Network by Conducting-Polymer-Assisted Joining for a Flexible Touch-Panel Application. Adv. Funct. Mater. 2013, 23 (34), 4171-4176. https://doi.org/10.1002/adfm.201203802.
(69) Lee, S. H.; Park, H.; Kim, S.; Son, W.; Cheong, I. W.; Kim, J. H. Transparent and Flexible Organic Semiconductor Nanofilms with Enhanced Thermoelectric Efficiency. J. Mater. Chem. A 2014, 2 (20), 7288-7294. https://doi.org/10.1039/C4TA00700J.
(70) Efremov, M. Y.; Schiettekatte, F.; Zhang, M.; Olson, E. A.; Kwan, A. T.; Berry, R. S.; Allen, L. H. Discrete Periodic Melting Point Observations for Nanostructure Ensembles. Phys. Rev. Lett. 2000. https://doi.org/10.1103/PhysRevLett.85.3560.
(71) Zhang, M.; Efremov, M. Y.; Schiettekatte, F.; Olson, E. A.; Kwan, A. T.; Lai, S. L.; Wisleder, T.; Greene, J. E.; Allen, L. H. Size-Dependent Melting Point Depression of Nanostructures: Nanocalorimetric Measurements. Phys. Rev. B—Condens. Matter Mater. Phys. 2000. https://doi.org/10.1103/PhysRevB.62.10548. 22
(72) Choo, D. C.; Kim, T. W. Degradation Mechanisms of Silver Nanowire Electrodes under Ultraviolet Irradiation and Heat Treatment. Sci. Rep. 2017. https://doi.org/10.1038/s41598-017-01843-9.
(73) De, S.; Higgins, T. M.; Lyons, P. E.; Doherty, E. M.; Nirmalraj, P. N.; Blau, W. J.; Boland, J. J.; Coleman, J. N. Silver Nanowire Networks as Flexible, Transparent, Conducting Fims: Extremely High DC to Optical Conductivity Ratios. ACS Nano 2009, 3 (7), 1767-1774.
(74) Zeng, X. Y.; Zhang, Q. K.; Yu, R. M.; Lu, C. Z. A New Transparent Conductor: Silver Nanowire Film Buried at the Surface of a Transparent Polymer. Adv. Mater. 2010, 22 (40), 4484-4488. https://doi.org/10.1002/adma.201001811.
(75) Gaynor, W.; Lee, J. Y.; Peumans, P. Fully Solution-Processed Inverted Polymer Solar Cells with Laminated Nanowire Electrodes. ACS Nano 2010, 4 (1), 30-34. https://doi.org/10.1021/nn900758e.
(76) Lee, J. Y.; Connor, S. T.; Cui, Y.; Peumans, P. Semitransparent Organic Photovoltaic Cells with Laminated Top Electrode. Nano Lett. 2010, 10 (4), 1276-1279. https://doi.org/10.1021/n1903892x.
(77) Yu, Z.; Zhang, Q.; Li, L.; Chen, Q.; Niu, X.; Liu, J.; Pei, Q. Highly Flexible Silver Nanowire Electrodes for Shape-Memory Polymer Light-Emitting Diodes. Adv. Mater. 2011, 23 (5), 664-668. https://doi.org/10.1002/adma.201003398.
(78) Volman, V.; Zhu, Y.; Raji, A. R. O.; Genorio, B.; Lu, W.; Xiang, C.; Kittrell, C.; Tour, J. M. Radio-Frequency-Transparent, Electrically Conductive Graphene Nanoribbon Thin Films as Deicing Heating Layers. ACS Appl. Mater. Interfaces 2014, 6 (1), 298-304. https://doi.org/10.1021/am404203y.
(79) Raji, A. R. O.; Varadhachary, T.; Nan, K.; Wang, T.; Lin, J.; Ji, Y.; Genorio, B.; Zhu, Y.; Kittrell, C.; Tour, J. M. Composites of Graphene Nanoribbon Stacks and Epoxy for Joule Heating and Deicing of Surfaces. ACS Appl. Mater. Interfaces 2016, 8 (5), 3551-3556. https://doi.org/10.1021/acsami.5b11131.
(80) Lu, H.-Y.; Chou, C.-Y.; Wu, J.-H.; Lin, J.-J.; Liou, G.-S. Highly Transparent and Flexible Polyimide-AgNW Hybrid Electrodes with Excellent Thermal Stability for Electrochromic Applications and Defogging Devices. J. Mater. Chem. C 2015, 3 (15), 3629-3635. https://doi.org/10.1039/C5TC00142K.
(81) Wang, J.; Fang, Z.; Zhu, H.; Gao, B.; Garner, S.; Cimo, P.; Barcikowski, Z.; Mignerey, A.; Hu, L. Flexible, Transparent, and Conductive Defrosting Glass. Thin Solid Films 2014, 556, 13-17. https://doi.org/10.1016/j.tsf.2013.12.060.
(82) Kim, H.; Gilmore, C. M.; Pique, A.; Horwitz, J. S.; Mattoussi, H.; Murata, H.; Kafafi, Z. H.; Chrisey, D. B. Electrical, Optical, and Structural Properties of Indium-Tin-Oxide Thin Films for Organic Light-Emitting Devices. J. Appl. Phys. 1999, 86 (11), 6451-6461. https://doi.org/10.1063/1.371708.
(83) Jin, J.; Lee, J.; Jeong, S.; Yang, S.; Ko, J.-H.; Im, H.-G.; Baek, S.-W.; Lee, J.-Y.; Bae, B.-S. High-Performance Hybrid Plastic Films: A Robust Electrode Platform for Thin-Film Optoelectronics. Energy Environ. Sci. 2013, 6 (6), 1811. https://doi.org/10.1039/c3ee24306k.
(84) Rathmell, A. R.; Nguyen, M.; Chi, M.; Wiley, B. J. Synthesis of Oxidation-Resistant Cupronickel Nanowires for Transparent Conducting Nanowire Networks. Nano Lett. 2012, 12 (6), 3193-3199. 23 https://doi.org/10.1021/nl301168r.
(85) Mayousse, C.; Celle, C.; Fraczkiewicz, A.; Simonato, J. Stability of Silver Nanowire Based Electrodes under Environmental and Electrical Stresses. Nanoscale 2015, 7, 2107-2115. https://doi.org/10.1039/c4nr06783e.
(86) Moon, I. K.; Kim, J. II; Lee, H.; Hur, K.; Kim, W. C.; Lee, H. 2D Graphene Oxide Nanosheets as an Adhesive Over-Coating Layer for Flexible Transparent Conductive Electrodes. Sci. Rep. 2013, 3, 1112. https://doi.org/10.1038/srep01112.
(87) Lee, D.-Y. D.; Lee, H.; Ahn, Y.; Jeong, Y.; Lee, D.-Y. D.; Lee, Y. Highly Stable and Flexible Silver Nanowire-Graphene Hybrid Transparent Conducting Electrodes for Emerging Optoelectronic Devices. Nanoscale 2013, 5 (17), 7750-7755. https://doi.org/10.1039/c3nr02320f.
(88) Ahn, Y.; Jeong, Y.; Lee, Y. Improved Thermal Oxidation Stability of Solution-Processable Silver Nanowire Transparent Electrode by Reduced Graphene Oxide. ACS Appl. Mater. Interfaces 2012, 4, 6410. https://doi.org/10.1021/am301913w.
(89) Kholmanov, I. N.; Domingues, S. H.; Chou, H.; Wang, X.; Tan, C.; Kim, J.-Y.; Li, H.; Piner, R.; Zarbin, A. J. G.; Ruoff, R. S. Reduced Graphene Oxide/Copper Nanowire Hybrid Films as High-Performance Transparent Electrodes. ACS Nano 1811, 7 (2), 1811-1816.
(90) Chen, Z.; Xu, C.; Ma, C.; Ren, W.; Cheng, H. M. Lightweight and Flexible Graphene Foam Composites for High-Performance Electromagnetic Interference Shielding. Adv. Mater. 2013, 25 (9), 1296-1300. https://doi.org/10.1002/adma.201204196.
(91) He, X.; He, R.; Lan, Q.; Wu, W.; Duan, F.; Xiao, J.; Zhang, M.; Zeng, Q.; Wu, J.; Liu, J. Screen-Printed Fabrication of PEDOT: PSS/Silver Nanowire Composite Films for Transparent Heaters. Materials (Basel). 2017. https://doi.org/10.3390/ma10030220.
(92) Kim, Y. S.; Chang, M. H.; Lee, E. J.; Ihm, D. W.; Kim, J. Y. Improved Electrical Conductivity of PEDOT-Based Electrode Films Hybridized with Silver Nanowires. Synth. Met. 2014, 195, 69-74. https://doi.org/10.1016/j.synthmet.2014.04.032.
(93) Hwang, B.; Lim, S. PEDOT:PSS Overcoating Layer for Mechanically and Chemically Stable Ag Nanowire Flexible Transparent Electrode. J. Nanomater. 2017, 2017. https://doi.org/10.1155/2017/1489186.
(94) Kim, Y. S.; Lee, E. J.; Lee, J. T.; Hwang, D. K.; Choi, W. K.; Kim, J. Y. High-Performance Flexible Transparent Electrode Films Based on Silver Nanowire-PEDOT:PSS Hybrid-Gels. RSC Adv. 2016, 6 (69), 64428-64433. https://doi.org/10.1039/c6ra06590b.
(95) Liu, Y. S.; Feng, J.; Ou, X. L.; Cui, H. F.; Xu, M.; Sun, H. B. Ultrasmooth, Highly Conductive and Transparent PEDOT:PSS/Silver Nanowire Composite Electrode for Flexible Organic Light-Emitting Devices. Org. Electron. 2016, 31, 247-252. https://doi.org/10.1016/j.orgel.2016.01.014.
(96) Kim, S.; Kim, S. Y.; Chung, M. H.; Kim, J.; Kim, J. H. A One-Step Roll-to-Roll Process of Stable AgNW/PEDOT:PSS Solution Using Imidazole as a Mild Base for Highly Conductive and Transparent Films: Optimizations and Mechanisms. J. Mater. Chem. C 2015, 3 (22), 5859-5868. https://doi.org/10.1039/c5tc00801 h.
(97) Chen, S.; Song, L.; Tao, Z.; Shao, X.; Huang, Y.; Cui, Q.; Guo, X. Neutral-PH PEDOT:PSS as over-Coating Layer for Stable Silver Nanowire Flexible Transparent Conductive Films. Org. Electron. 24 physics, Mater. Appl. 2014, 15 (12), 3654-3659. https://doi.org/10.1016/j.orgel.2014.09.047.
(98) Jung, E. D.; Nam, Y. S.; Seo, H.; Lee, B. R.; Yu, J. C.; Lee, S. Y.; Kim, J. Y.; Park, J. U.; Song, M. H. Highly Efficient Flexible Optoelectronic Devices Using Metal Nanowire-Conducting Polymer Composite Transparent Electrode. Electron. Mater. Lett. 2015, 11 (5), 906-914. https://doi.org/10.1007/s13391-015-5120-z.
(99) Choi, D. Y.; Kang, H. W.; Sung, H. J.; Kim, S. S. Annealing-Free, Flexible Silver Nanowire-Polymer Composite Electrodes via a Continuous Two-Step Spray-Coating Method. Nanoscale 2013, 5 (3), 977-983. https://doi.org/10.1039/c2nr32221 h.
(100) Zhu, R.; Chung, C. H.; Cha, K. C.; Yang, W.; Zheng, Y. B.; Zhou, H.; Song, T. Bin; Chen, C. C.; Weiss, P. S.; Li, G.; et al. Fused Silver Nanowires with Metal Oxide Nanoparticles and Organic Polymers for Highly Transparent Conductors. ACS Nano 2011, 5 (12), 9877-9882. https://doi.org/10.1021/nn203576v.
(101) Lim, J. E.; Lee, S. M.; Kim, S. S.; Kim, T. W.; Koo, H. W.; Kim, H. K. Brush-Paintable and Highly Stretchable Ag Nanowire and PEDOT:PSS Hybrid Electrodes. Sci. Rep. 2017. https://doi.org/10.1038/s41598-017-14951-3.
(102) Stapleton, A. J.; Yambem, S.; Johns, A. H.; Gibson, C. T.; Shearer, C. J.; Ellis, A. V.; Shapter, J. G.; Andersson, G. G.; Quinton, J. S.; Burn, P. L.; et al. Pathway to High Throughput, Low Cost Indium-Free Transparent Electrodes. J. Mater. Chem. A 2015. https://doi.org/10.1039/c5ta03248b.

EMI Shielding Equations

Total EMI Shielding Effectiveness:

SE_{T}=SE_{A}+SE_{R}+SE_{M} (S1)
where SE_{T} is the overall shielding effectiveness, SE_{A}, SE_{R} and SE_{M} are the shielding effectiveness due to absorption (absorption loss), reflection and multiple internal reflection, respectively.

EMI Reflection Loss:

$${SE}_{R} = 168 + 10 log ( \frac{σ}{μ f} ) = 10 log ( \frac{1}{1 - R} ) \qquad ( S2 )$$

where σ is the conductivity, μ is the magnetic permeability of the shield relative to the air, f is the frequency in Hz and R is the reflectance.

EMI Absorption Loss:

$${SE}_{A} = 8 \text{.68} t ( \sqrt{\frac{σ ω μ}{2}} ) = 8.68 \frac{t}{δ} = 10 log ( \frac{1 - R}{T} ) \qquad ( S3 )$$

where t is the thickness of the shield, ω is the angular frequency in rad s₋₁, δ is the skin depth of the shield, and T is the transmittance.

Figure of Merit

$$T ( λ ) = {( 1 + \frac{188.5}{{R}_{s}} \frac{{σ}_{OP}}{{σ}_{DC}} )}^{- 2} \qquad ( S4 )$$

where T is the transmission, Rₛ, the sheet resistance in Ωsq₋₁ and Γ_{DC}/σ_{OP} is the figure of merit.

### REFERENCES

1. Colegrove, J. ITO Replacement-Non-ITO Transparent Conductor Technologies, Supply Chain and Market Forecast. (2019).
2. Hoffmann, K. A. & Chiang, S. T. Computational fluid dynamics. (Engineering Education System, 2000).

The embodiments described herein are intended to be examples only. Alterations, modifications, and variations can be affected to the particular embodiments by those of skill in the art. The scope of the claims should not be limited by the particular embodiments set forth herein but should be construed in a manner consistent with the specification as a whole.

All publications, patents, and patent applications mentioned in this Specification are indicative of the level of skill those skilled in the art to which this invention pertains and are herein incorporated by reference to the same extent as if each individual publication patent or patent application was specifically and individually indicated to be incorporated by reference.

The invention being thus described, it will be obvious that the same may be varied in many ways. Such variations are not to be regarded as a departure from the spirit and scope of the invention, and all such modifications as would be obvious to one skilled in the art are intended to be included within the scope of the following claims.

What is claimed is:

1. A method of producing a film, comprising:
applying a first layer of PEFOT:PSS on a substrate, and subjecting said first layer to a first annealing temperature for a first annealing time,
applying an AgNW layer on said first layer of PEFOT:PSS, and subjecting said AgNW layer to an AgNW annealing temperature for an AgNW annealing time, and
applying a second layer of PEDOT:PSS on the AgNWs layer, and subjecting said second layer to a second annealing temperature for a second annealing time.

2. The method of claim 1, wherein said applying comprises spin coating.

3. The method of claim 1 or 2, wherein said first annealing temperature is about 120° C. to 180° C., preferably 160° C., and said second annealing is about 120° C. to 180° C., preferably about 160° C.

4. The method of any one of claims 1 to 3, wherein said first annealing time is about 5 minutes to 30 minutes, preferably 10 minutes, and said second annealing time is about 5 minutes to 30 minutes, preferably about 10 minutes.

5. The method of any one of claims 1 to 4, wherein said AgNW annealing temperature is about 60° C. to 160° C., preferably about 120° C.

6. The method of any one of claims 1 to 5, wherein said AgNW is AgNWs-30, AgNWs-60, or AgNWs-90.

7. The method of any one of claims 1 to 6, wherein the concentration of AgNW used in the coating step is about 0.1 mg/ml to 15 mg/ml, preferably about 5 mg/ml.

8. The method of any one of claims 1 to 7, wherein said first layer of PEFOT:PSS has a thickness of about 2 nm to 100 nm, preferably about 20 nm, and said second layer of PEFOT:PSS has a thickness of about 2 nm to 100 nm, preferably about 20 nm.

9. The method of any one of claims 1 to 8, wherein said substrate comprises or consists of glass or silicon.

10. The method of any one of claims 1 to 9, where the film has a thickness of about 5 nm to 150 nm, preferably about 80 nm

11. A film produce by the method of any one of claims 1-10.

12. The film of claim 11, wherein the film has a transparency of greater than above 80%, preferably greater than about 90%.

13. The film of claim 11, wherein the film has an EMI shielding effectiveness of 10 dB to 50 dB, preferably 23 dB when used as a transparent EMI shield.

14. A film produce by the method of any one of claims 1-10 for use in deicing.

15. A film produce by the method of any one of claims 1-10 for use in EMI shielding.
